(19) United States
(12) Patent Application Publication
(10) Pub. No.: US 2010/0154882 A1
(43) Pub. Date: Jun. 24, 2010

(54) SOLAR CELL

(75) Inventors: Yi-Chan Chen, Yunlin County (TW); Hsuan-Yin Fang, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/403,353

(22) Filed: Mar. 12, 2009

(30) Foreign Application Priority Data
Dec. 24, 2008 (TW) 97150530

(51) Int. Cl. H01L 31/04

(52) U.S. Cl. 136/256

(57) ABSTRACT

A solar cell is provided and includes a front contact, a first conductive type layer, an intrinsic (I) layer, a second conductive type layer, and a back contact. The first conductive type layer is a material layer of low refractive index which has a refractive index lower than 3. The material layer with low refractive index was used to increase light transmittance of the solar cell and decrease reflection which occurs at interfaces in the solar cell, and thus the solar cell has an optimum sunlight utility rate. Therefore, the solar cell has a large short circuit current (Jsc) and high efficiency.

### CROSS-REFERENCE TO RELATED APPLICATION

This application claims the priority benefit of Taiwan application serial no. 97150530, filed on Dec. 24, 2008. The entirety of the above-mentioned patent application is hereby incorporated by reference herein and made a part of this specification.

### BACKGROUND OF THE INVENTION

1. Field of the Invention

The present invention is related to a solar cell capable of achieving the optimum utility rate of the sunlight.

2. Description of Related Art

The solar energy is a non-polluting and inexhaustible energy source. When petrochemical energy sources confront with problems such as pollution and shortage, the mass has gradually focused on the issue of how to utilize the solar energy source efficiently. As solar cells can convert solar energy into electric energy directly, the solar cells have become a key point currently in terms of utilizing the solar energy.

A known solar cell converts light energy into electrical energy with a P-I-N junction structure. Specifically, the solar cell includes a front contact, a P-type semiconductor layer, an intrinsic layer (i.e., an I layer), an N-type semiconductor layer and a back contact stacked on one another. The intrinsic layer serves as the primary area which generates pairs of electrons and holes. The P-type semiconductor layer and the N-type semiconductor layer above and under the intrinsic layer form a strong electric field, which then causes the electrons and holes to separate from each other, thus generating currents.

However, sunlight may be reflected at interfaces of the solar cell (e.g., the interface between the front contact and the P-type semiconductor layer, the interface between the P-type semiconductor layer and the intrinsic layer or the interface between the intrinsic layer and the N-type semiconductor layer), such that the solar cell cannot effectively utilize the sunlight, thereby resulting in low short current density and poor efficiency of the solar cell.

### SUMMARY OF THE INVENTION

Accordingly, the present invention is directed to a solar cell capable of increasing light transmittance and reducing light reflection occurring at interfaces of the solar cell.

As embodied and broadly described herein, the present invention provides a solar cell, which includes a front contact, a first conductive type layer, an intrinsic layer, a second conductive type layer and a back contact stacked on one another. The solar cell is characterized by the first conductive type layer being a material layer with low refractive index, and a refractive index of the material layer with low refractive index is lower than 3.

Based on the above, a material layer of low refractive index having a refractive index lower than 3 is disposed as the first conductive type layer in the solar cell according to the present invention, so that light transmittance can be increased and light reflection occurring at interfaces can be reduced. Therefore, the solar cell achieves the optimum utility rate of sunlight, which in turn enhances a short circuit current density (Jsc) and efficiency of the solar cell.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a solar cell according to an embodiment of the present invention.

FIG. 2 is a schematic cross-sectional view of a solar cell according to another embodiment of the present invention.

FIG. 3 is a curve diagram of reflection indexes of solar cells according to the present invention and a comparison example changing with wavelengths.

FIG. 4 is a curve diagram of quantum efficiencies of solar cells according to the present invention and a comparison example changing with wavelengths.

### DESCRIPTION OF EMBODIMENTS

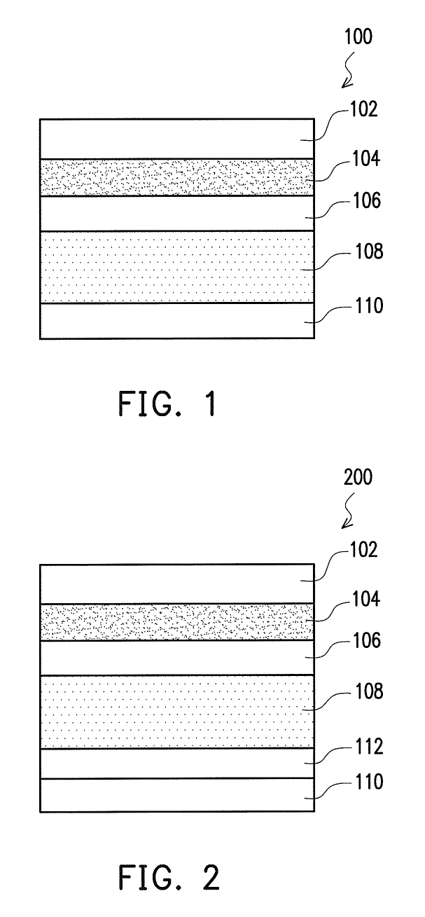

FIG. 1 is a schematic cross-sectional view of a solar cell according to an embodiment of the present invention.

Referring to FIG. 1, in the present embodiment, a solar cell 100 includes a front contact 102, a material layer 104 with low refractive index serving as a first conductive type layer, an intrinsic layer 106, a second conductive type layer 108 and a back contact 110 stacked on one another. A refractive index of the material layer 104 with low refractive index is lower than 3. According to the present embodiment, a refractive index of the material layer 104 is about 1.8-3, for example, preferably 1.8-2.5, and more preferably 2-2.3. A thickness of the material layer 104 of low refractive index is substantially thinner than 100 nm, preferably thinner than 60 nm. According to the present embodiment, the material layer 104 of low refractive index serves as an N-type layer, for example, and a material thereof can be selected from μc-SiOx, μc-SiCOx and μc-SiONx. For example, when the material layer 104 with low refractive index is an N-μc-SiOx layer, the refractive index of the N-μc-SiOx layer is 2.1, and a conductivity thereof is larger than or equal to 10⁻⁴ S/cm, preferably about 3.52×10⁻⁴ S/cm.

In this embodiment, the refractive index of the front contact 102 is lower than or equal to 1.8, and the thickness thereof is 60-140 nm, for example. The material of the front contact 102 is transparent conductive oxide (TCO), for example, which can be selected from ITO, ZnO, AlZnO, SnO₂ and In₂O₃. The refractive index of the intrinsic layer 106 is 4, the thickness thereof is 5-30 nm, and the material thereof is a-Si or hydrogenated amorphous silicon (a-Si:H), for example. The second conductive type layer 108 is a P-type layer, the refractive index thereof is 4.5, and the thickness thereof is 50 μm-150 μm, for example. The material of the second conductive type layer 108 is single-c-Si or poly-c-Si, for example. The material of the back contact 110 is transparent conductive oxide (TCO) or a metal layer, and the material of the metal layer is Al, Ag, Mo, Cu or other suitable metals or alloys, for example.

It should be noted that in the solar cell 100, the refractive indexes of the front contact 102, the material layer 104 with low refractive index serving as the first conductive type layer, the intrinsic layer 106 and the second conductive type layer 108 as stacked increase in sequence. As a result, incident light is prevented from being reflected at interfaces, e.g., the interface between the front contact 102 and the material layer 104 of low refractive index, the interface between the material layer 104 with low refractive index and the intrinsic layer 106, and the interface between the intrinsic layer 106 and the second conductive type layer 108. Moreover, the present embodiment is exemplified by the material layer 104 with low refractive index serving as an N-type layer and the second conductive type layer 108 being a P-type layer. However, according to another embodiment (not shown), the material layer 104 of low refractive index can also be a P-type layer, and the second conductive type layer 108 can be an N-type layer. In other words, the material layer 104 with low refractive index having a refractive index lower than 3 in the solar cell 100 can serve as an N-type layer or a P-type layer.

It should be pointed out that in the solar cell 100 shown by FIG. 1, when the material layer 104 with low refractive index serves as the P-type layer and the second conductive type layer 108 serves as the N-type layer, the solar cell 100 further includes a back surface field (BSF) layer. Specifically, as shown in FIG. 2, a solar cell 200 has a structure similar to the structure of the solar cell 100 shown in FIG. 1. The primary difference between the two solar cells lies in that the solar cell 200 further includes a back surface field (BSF) layer 112. Herein, the material layer 104 with low refractive index is the P-type layer, the second conductive type layer 108 is the N-type layer, and the back surface field (BSF) layer 112 is disposed between the second conductive type layer 108 and the back contact 110. The material of the back surface field (BSF) layer 112 is, for example, Al, which enhances power-generating ability of the solar cell 200.

In the foregoing embodiment, the refractive index of the material layer 104 of low refractive index serving as the first conductive type layer is lower than 3, and the refractive indexes of the front contact 102, the material layer 104 with low refractive index, the intrinsic layer 106 and the second conductive type layer 108 increase in sequence. As a result, light transmittance is enhanced and occurrence of light reflection at the interfaces is reduced (e.g., the interface between the front contact 102 and the material layer 104 with low refractive index, the interface between the material layer 104 of low refractive index and the intrinsic layer 106, and the interface between the intrinsic layer 106 and the second conductive type layer 108). Hence, the solar cells 100 and 200 achieve the optimum utility rate of sunlight, which in turn enhances short circuit current densities (Jsc) and efficiencies of the solar cells 100 and 200.

It is to be noted that in the foregoing embodiment the material of the intrinsic layer 106 is a-Si, and the material of the second conductive type layer 108 is silicon. Hence, the solar cell 100 is a hetero -junction solar cell. In the conventional hetero-junction solar cell, since an absorption coefficient of a-Si is higher than the absorption coefficient of silicon, sunlight is largely absorbed by an a-Si layer before it enters a silicon layer such that photoelectric current of the hetero-junction solar cell is significantly reduced. However, the structure of the solar cell in the present invention significantly enhances transmittance of sunlight and reduces light reflection at the interfaces so that more sunlight reaches the silicon layer to solve the aforementioned problems, thereby enhancing the utility rate of sunlight, the short circuit current density and the efficiency of the hetero-junction solar cell.

Several experiment examples are described below to prove the efficacy of the present invention.

### EXPERIMENT EXAMPLE 1

In order to compare the influence of the material layer of low refractive index in the short circuit current density (Jsc) and the refractive index, a solar cell having a material layer with low refractive index (n) lower than 3 is manufactured first. The solar cell includes a 140-nm TCO layer serving as the front contact (n=1.8-2), a 60-nm N-μc-SiOx layer (n=2-2.3) serving as the N-type layer, a 30-nm a-Si layer (n=4) serving as the intrinsic layer, a 150-nm P-type silicon layer (n=4.5) serving as the P-type layer and a metal layer serving as the back contact.

In addition, another solar cell is manufactured as a comparison example, and the solar cell of the comparison example differs from that of the experiment example only in that a 60-nm N-type a-Si layer (n=4.5) is used as the conventional N-type layer in the solar cell of the comparison example.

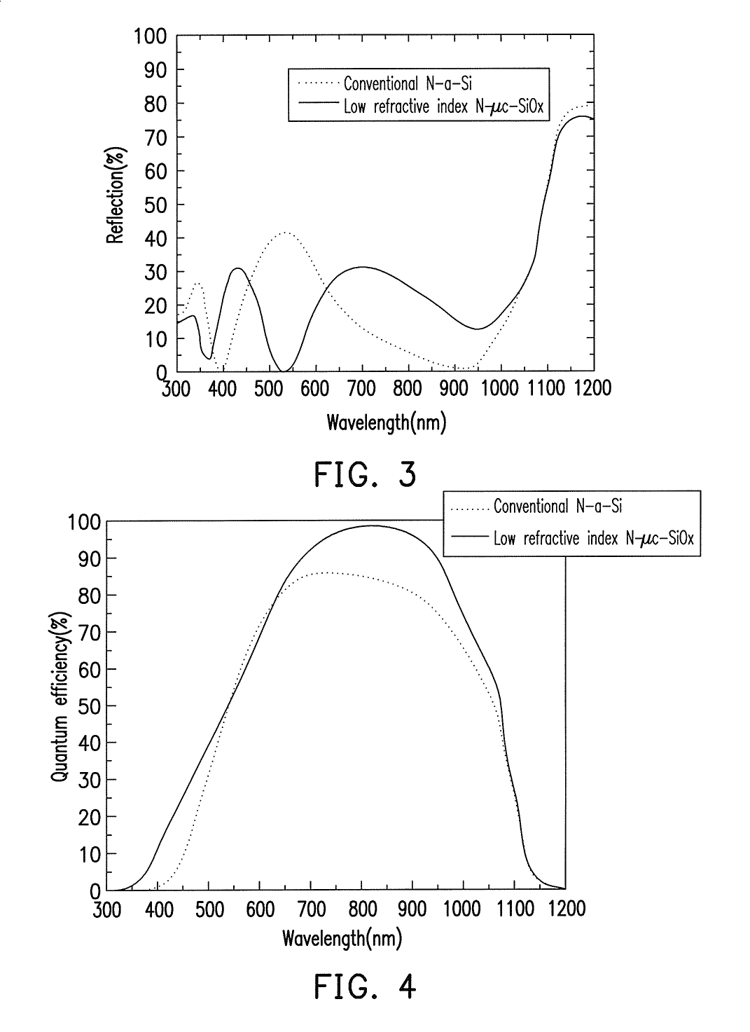

Afterwards, light of different wavelengths irradiates the solar cells of the present invention and the comparison example through the front contact, and then the refractive indexes of the solar cells are measured and the short circuit current densities (Jsc) thereof are computed. FIG. 3 is a curve diagram showing the reflection indexes varying with different wavelengths.

It is known from FIG. 3 that when the N-μc-SiOx layer having a refractive index lower than 3 in the solar cell substitutes the conventional N-type layer, the reflection index of the solar cell is reduced by 30-40%. Furthermore, the short current circuit density (Jsc) of the solar cell in the comparison example is 26.69 mA/cm², and the Jsc of the solar cell in the present invention is 27.78 mA/cm². In other words, when the N-μc-SiOx layer having a refractive index lower than 3 substitutes the conventional N-type layer in the solar cell, the Jsc of the solar cell is increased by 4.08%.

### EXPERIMENT EXAMPLE 2

According to the present experiment example, the thicknesses of the TCO layers serving as the front contacts in the solar cells of the present invention and the comparison example are reduced to 60 nm, the materials and parameters of the remaining layers are all the same as those described in the experiment example 1.

Afterwards, light of different wavelengths irradiates the solar cells of the present invention and the comparison example through the front contact, and then quantum efficiencies (QE) of the solar cells are measured and the short current densities (Jsc) thereof are computed. The quantum efficiencies varying with different wavelengths are shown by the curve diagram of FIG. 4.

It is known from FIG. 4 that when the N-μc-SiOx layer having a refractive index lower than 3 in the solar cell substitutes the conventional N-type layer and the thickness of the TCO layer is reduced to 60 nm, the quantum efficiency of the solar cell is enhanced by 20%. The Jsc of the solar cell in the comparison example is 27.61 mA/cm², while the Jsc of the solar cell in the present invention is 31.1 mA/cm². In other words, when the N-μc-SiOx layer having a refractive index lower than 3 in the solar cell substitutes the conventional N-type layer, the Jsc of the solar cell is increased by 12.64%.

It is known from the foregoing experiment examples that the material layer with low refractive index having a refractive index lower than 3 in the present invention reduces the probability of light reflection and enhances the short circuit current density (Jsc) in the solar cell. Moreover, the thickness reduction of the TCO layer allows the solar cell of the present invention to obtain a higher Jsc and higher efficiency.

In summary, the solar cell of the present invention has the material layer of low refractive index having a refractive index lower than 3 to serve as the first conductive type layer, and the refractive indexes of the front contact, the material layer of low refractive index, the intrinsic layer and the second conductive type layer increase in sequence, for example. Consequently, sunlight transmittance is increased and light reflection at the interfaces is reduced (e.g., the interface between the front contact and the material layer of low refractive index, the interface between the material layer of low refractive index and the intrinsic layer, and the interface between the intrinsic layer and the second conductive type layer). Therefore, the solar cell achieves the optimum utility rate of sunlight, which in turn enhances the short current density (Jsc) and efficiency. Additionally, the solar cell structure of the present invention can be applied to a hetero-junction solar cell to solve the problem of insufficient photoelectric current in the heterojunction cell because light is largely absorbed by the a-Si layer, thus enhancing the utility rate of sunlight, the short circuit current density and efficiency of the hetero-junction solar cell.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell, comprising: a front contact, a first conductive type layer, an intrinsic layer, a second conductive type layer and a back contact stacked on one another, wherein the solar cell is characterized by
the first conductive type layer being a material layer with low refractive index, and a refractive index of the material layer is lower than 3.

2. The solar cell as claimed in claim 1, wherein a material of the material layer of low refractive index comprises μc-SiOx, μc-SiCOx or μc-SiNOx.

3. The solar cell as claimed in claim 1, wherein the refractive index of the material layer of low refractive index is lower than 2.5.

4. The solar cell as claimed in claim 1, wherein the refractive index of the material layer with low refractive index is higher than 1.8.

5. The solar cell as claimed in claim 1, wherein a thickness of the material layer of low refractive index is thinner than 100 nm.

6. The solar cell as claimed in claim 5, wherein the thickness of the material layer with low refractive index is thinner than or equal to 60 nm.

7. The solar cell as claimed in claim 1, wherein the first conductive type layer is an N-type layer, and the second conductive type layer is an N-type layer.

8. The solar cell as claimed in claim 1, wherein the first conductive type layer is a P-type layer, and the second conductive type layer is an N-type layer.

9. The solar cell as claimed in claim 8, further comprising a back surface field layer disposed between the second conductive type layer and the back contact.

10. The solar cell as claimed in claim 1, wherein a conductivity of the N-μc-SiOx layer is larger than or equal to 10⁻⁴ S/cm when the material layer of low refractive index is an N-μc-SiOx layer.

11. The solar cell as claimed in claim 1, wherein the refractive index of the material layer of low refractive index is higher than that of the front contact, and the refractive index of the material layer with low refractive index is lower than that of the intrinsic layer.

12. The solar cell as claimed in claim 1, wherein the refractive index of the intrinsic layer is lower than that of the second conductive type layer.
